(19) United States
(12) Patent Application Publication
(10) Pub. No.: US 2026/0026146 A1
(43) Pub. Date: Jan. 22, 2026

(54) STAMP ASSEMBLY, LIGHT EMITTING ELEMENT TRANSFER DEVICE, AND TRANSFER METHOD THEREOF

(71) Applicant: Samsung Display Co., LTD., Yongin-si (KR)

(72) Inventor: Jeong Won HAN, Yongin-si (KR)

(21) Appl. No.: 19/055,781

(22) Filed: Feb. 18, 2025

(30) Foreign Application Priority Data
Jul. 16, 2024 (KR) 10-2024-0093777

(51) Int. Cl. H10H 29/02; H01F 7/02; H01L 21/67

(52) U.S. Cl. CPC H10H 29/02; H01F 7/02; H01L 21/67144

(57) ABSTRACT

A stamp assembly includes a stamp member including a stamp layer and a base layer, a magnetic plate which applies a magnetic force on a top surface of the base layer and a plurality of magnetic beads which are attachable and detachable to the stamp layer by the magnetic force of the first magnetic plate.

This application claims priority to Korean Patent Application No. 10-2024-0093777, filed on Jul. 16, 2024, and all the benefits accruing therefrom under 35 U.S.C. § 119, the content of which in its entirety is herein incorporated by reference.

### BACKGROUND

### 1. Field

Embodiments of the disclosure relate to a stamp assembly, a light emitting element transfer device and a transfer method thereof.

### 2. Description of the Related Art

The importance of display devices is increasing along with the development of multimedia. Accordingly, various types of display devices such as organic light emitting display devices (OLED) and liquid crystal display devices (LCD), etc. are widely used in various fields.

A display panel such as a light emitting display panel or a liquid crystal display panel is included as a device that displays an image of a display device. Among various types of display panel, the light emitting display panel may include a light emitting diode (LED), and an organic light emitting diode that uses an organic substance as a fluorescent material or an inorganic light emitting diode that uses an inorganic substance as a fluorescent material may be included as the light emitting diode.

When manufacturing a display panel that uses an inorganic light emitting diode as a light emitting diode, manufacturing devices for arranging micro light emitting diode on a substrate of the display panel may be used.

### SUMMARY

Embodiments of the disclosure provide a stamp assembly, a transfer device, and a method to effectively prevent a light emitting element from remaining on a donor substrate or on one side of a stamp in a light emitting element transfer process.

However, the disclosure is not limited to those set forth herein. The above and other embodiments of the disclosure will become more apparent to one of ordinary skill in the art to which the disclosure pertains by referencing the detailed description of the disclosure given below.

According to one or more embodiments of the disclosure, the stamp assembly includes a stamp member including a stamp layer and a base layer, a magnetic plate which applies a magnetic force on a top surface of the base layer and a plurality of magnetic beads which are attachable and detachable to the stamp layer by the magnetic force of the first magnetic plate.

According to one or more embodiments, the magnetic beads may be ferromagnetic particles having a size of about 10 nanometers (nm) or less.

According to one or more embodiments, the stamp layer may be divided into a first area where the magnetic beads are not disposed and a second area where the magnetic beads are not disposed, where the first area may include a plurality of sub-areas.

According to one or more embodiments, the sub-areas may correspond to positions where the light emitting elements are to be attached, and an area of the sub-areas may be smaller than the area of one surface of the light emitting elements.

According to one or more embodiments, a surface portion of the stamp layer may have elasticity and adhesiveness on one surface.

According to one or more embodiments, the first magnetic plate may be an electromagnet or a permanent magnet.

According to one or more embodiments of the disclosure, a light emitting element transfer device includes a stage which supports a substrate, a stamp member including a stamp layer and a base layer, a first magnetic plate which applies a magnetic force on a top surface of the base layer, a plurality of magnetic beads which are attachable and detachable to the stamp layer by the magnetic force of the first magnetic plate, and a second magnetic plate which is disposed on a bottom surface of the stage and applies a magnetic force to the bottom surface of the stage.

According to one or more embodiments, the stamp layer may be divided into a first area where the magnetic beads are not disposed and a second area where the magnetic beads are not disposed, where the first area may include a plurality of sub-areas.

According to one or more embodiments, the sub-areas may correspond to positions where the light emitting elements are to be attached, and an area of the sub-areas may be smaller than an area of one side of the light emitting elements.

According to one or more embodiments, the substrate may include at least one selected from a donor substrate, on which the light emitting elements are disposed, and a target substrate, to which the light emitting elements are to be transferred from the donor substrate.

According to one or more embodiments, a surface portion of the stamp layer may have elasticity and adhesiveness.

According to one or more embodiments, each of the first magnetic plate and the second magnetic plate may be an electromagnet or a permanent magnet.

According to one or more embodiments of the disclosure, a method for transferring light emitting elements includes arranging a plurality of magnetic beads on one surface of a stamp member, disposing the stamp member on a donor substrate in a way such that the magnetic beads face light emitting elements on the donor substrate, lifting the light emitting elements with the stamp member, disposing the stamp member on a target substrate in a way such that the light emitting elements face the target substrate, disposing a first magnetic plate under the target substrate and transferring the light emitting elements and the magnetic beads to the target substrate; and disposing a second magnetic plate on a top surface of the stamp member and recovering the magnetic beads.

According to one or more embodiments, the stamp member includes a stamp layer having adhesiveness on one surface of the light emitting elements, and in the lifting the light emitting elements with the stamp member, the light emitting elements are lifted by applying a pressure to adhere the light emitting elements to the stamp layer.

According to one or more embodiments, where the stamp layer may be divided into a first area where the magnetic beads are not disposed and a second area where the magnetic beads are disposed, where the first area may include a plurality of sub-areas, the sub-areas may correspond to positions where the light emitting elements are to be attached, and an area of the sub-areas may be smaller than an area of one surface of the light emitting elements.

According to one or more embodiments, when the stamp member comes into contact with the light emitting elements, some of the magnetic beads disposed in the second area and surrounding the sub-areas may be disposed on a top surface of the light emitting elements and embedded into a stamp layer of the stamp member by the pressure of the stamp member, such that one surface of the light emitting elements is adhered to the stamp layer.

According to one or more embodiments, the method may further include disposing a first magnetic plate under the target substrate and the transferring the light emitting elements and a plurality of magnetic beads to the target substrate, where the first magnetic plate may be disposed under the target substrate and the magnetic beads disposed on one side of the stamp member may be pulled in a downward direction by a magnetic force of the first magnetic plate, and the magnetic beads overlapping an upper portion of the light emitting elements may press the light emitting elements in the downward direction.

According to one or more embodiments, the first magnetic plate may be a permanent magnet disposed close to a lower portion of the target substrate to exert the magnetic force on the magnetic bead.

According to one or more embodiments, the first magnetic plate may be a magnetic force on the magnetic bead by applying an electric current by an electromagnet fixed to a lower portion of a stage, on which the target substrate is disposed, and the first magnetic plate may exert the magnetic force on the magnetic bead by applying an electric current thereto.

According to one or more embodiments, the recovering the magnetic beads may include disposing a second magnetic plate on a top surface of the stamp member, where disposing the second magnetic plate disposed on the top surface of the stamp member may cause an attraction between the second magnetic plate and the magnetic beads to move the magnetic beads from the target substrate and a top surface of the light emitting elements to a bottom surface of the stamp member.

According to embodiments of the disclosure, by using a magnetic bead to pick up a light emitting element, light emitting elements may be completely transferred during transfer and effectively prevented from being left on the donor substrate or stamp. Accordingly, the product quality and yield of the display device during the transfer process may be increased.

In such embodiments, since the repair process and stamp cleaning process may be omitted, the equipment cost and process progress cost may be reduced.

However, the effects of the disclosure are not limited to the aforementioned effects, and various other effects are included in the disclosure.

### BRIEF DESCRIPTION OF THE DRAWINGS

The above and other features of embodiment of the disclosure will become more apparent by describing in detail embodiments thereof with reference to the attached drawings, in which:

FIG. 1 is a plan view illustrating a display device according to an embodiment.

FIG. 2 is a diagram illustrating an embodiment of a pixel of FIG. 1.

FIG. 3 is a diagram illustrating another embodiment of a pixel of FIG. 1.

FIG. 4 is a cross-sectional view illustrating an embodiment of a display panel taken along line A-A′ of FIG. 2.

FIG. 5 is a side view illustrating the structure of a stamp assembly according to an embodiment.

FIG. 6 is a front view illustrating a plurality of magnetic beads disposed on one surface of a stamp member according to an embodiment.

FIG. 7 is a side view illustrating the structure of a stamp assembly according to an embodiment.

FIG. 8 is a diagram illustrating a light emitting element transfer device according to an embodiment.

FIG. 9 is a flow chart illustrating a light emitting element transfer method according to an embodiment.

FIGS. 10 to 19 are cross-sectional views to illustrate a light emitting element transfer method according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

Some of the parts which are not associated with the description may not be provided in order to describe embodiments of the disclosure.

It will also be understood that when a layer is referred to as being “on” another layer or substrate, it can be directly on the other layer or substrate, or intervening layers may be present therebetween. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, “Or” means “and/or.” As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the disclosure will be described in detail with reference to the accompanying drawings.

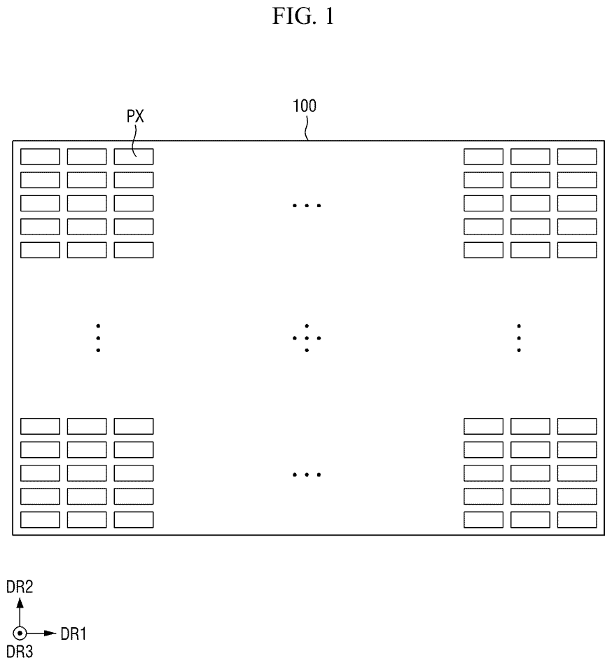

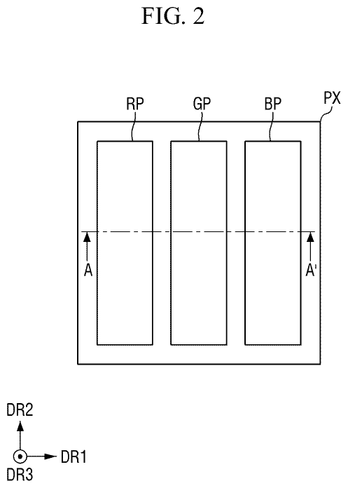

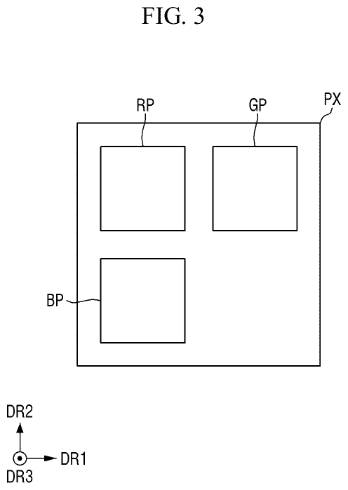

FIG. 1 is a plan view illustrating a display device according to an embodiment. FIG. 2 is a diagram illustrating an embodiment of a pixel of FIG. 1. FIG. 3 is a diagram illustrating another embodiment of a pixel of FIG. 1.

Referring to FIGS. 1 to 3, a display device 10 is a device for displaying video or still images, such as mobile phones, smart phones, tablet personal computers (PCs). For example, the display device 10 may be any of portable electronic devices such as smart watches, watch phones, mobile communication terminals, electronic notebooks, e-books, portable multimedia players (PMP), navigation, and ultra mobile PCs (UMPC). In addition, the display device 10 may be any electronic device including a display screen such as televisions, laptops, monitors, billboards, and the internet of things (IoT) device.

The display panel 100 may have a rectangular planar shape having a long side in a first direction DR1 and a short side in a second direction DR2 intersecting the first direction DR1 in a plan view or when viewed in a third direction DR3. Here, the third direction may be a thickness direction of the display panel 100 or a direction perpendicular to the first direction DR1 and the second direction DR2. A corner where the long side in the first direction DR1 and the short side in the second direction DR2 meet may be formed rounded to have a predetermined curvature or formed at a right angle. The planar shape of the display panel 100 is not limited to a rectangle, and may be formed in other polygonal, circular, or oval shapes. The display panel 100 may be formed flat but is not limited thereto. For example, the display panel 100 is formed at left and right ends and may include curved portions with a constant curvature or a changing curvature. Additionally, the display panel 100 may be formed to be flexible, such as to be able to be bent, curved, bent, folded, or rolled.

The display panel 100 may further include pixels PX for displaying an image, scan lines extending in the first direction DR1, and data lines extending in the second direction DR2. The pixels PX may be disposed in a matrix form with rows in the first direction DR1 and columns in the second direction DR2.

Each of the pixels PX may include a plurality of sub-pixels RP, GP, and BP as shown in FIGS. 2 and 3. In an embodiment, as shown in FIGS. 2 and 3, each of the pixels PX includes three sub-pixels RP, GP, and BP, that is, a first sub-pixel RP, a second sub-pixel GP, and a third sub-pixel BP, but the embodiment of the disclosure is not limited thereto.

Each of the first sub-pixel RP, the second sub-pixel GP, and the third sub-pixel BP may be connected to a corresponding data line of the data lines and a corresponding scan line among the scan lines.

Each of the first sub-pixel RP, the second sub-pixel GP, and the third sub-pixel BP may have a planar shape of a rectangle, a square, or a rhombus in the plan view. In an embodiment, for example, each of the first sub-pixel RP, the second sub-pixel GP, and the third sub-pixel BP may have a planar shape of a rectangle having a short side in the first direction DR1 and a long side in the second direction DR2, as shown in FIG. 2. Alternatively, each of first sub-pixel RP, the second sub-pixel GP, and the third sub-pixel BP may have a planar shape of a square or a rhombus including sides having the same length in the first direction DR1 and the second direction DR2, as shown in FIG. 3.

In an embodiment, as shown in FIG. 2, the first sub-pixel RP, the second sub-pixel GP, and the third sub-pixel BP may be disposed or arranged in the first direction DR1. Alternatively, one of the second sub-pixel GP and the third sub-pixel BP and the first sub-pixel RP may be disposed in the first direction DR1, and the other one and the first sub-pixel RP may be disposed in the second direction DR2. In an embodiment, for example, as shown in FIG. 3, the first sub-pixel RP and the second sub-pixel GP may be disposed in the first direction DR1, and the first sub-pixel RP and the third sub-pixel BP may be disposed in the second direction DR2.

Alternatively, one of the first sub-pixel RP and the third sub-pixel BP and the second sub-pixel GP may be disposed in the first direction DR1, and the other one and the second sub-pixel GP may be disposed in the second direction DR2. Alternatively, one of the first sub-pixel RP and the second sub-pixel GP and the third sub-pixel BP may be disposed in the first direction DR1, and the remaining one and the third sub-pixel BP may be disposed in the second direction DR2.

The first sub-pixel RP may include a first light emitting element that emits a first light, the second sub-pixel GP may include a second light emitting element that emits a second light, and the third sub-pixel BP may include a third light emitting element that emits third light. Here, the first light may be light in a red wavelength band, the second light may be light in a green wavelength band, and the third light may be light in a blue wavelength band. The red wavelength band may be a wavelength band of about 600 nanometers (nm) to about 750 nm, the green wavelength band may be a wavelength band of about 480 nm to about 560 nm, and the blue wavelength band may be a wavelength band of about 370 nm to about 460 nm, but the embodiments of the disclosure are not limited thereto.

Each of the first sub-pixel RP, the second sub-pixel GP, and the third sub-pixel BP may include an inorganic light emitting element having an inorganic semiconductor as a light emitting element that emits light. In an embodiment, for example, the inorganic light emitting element may be a micro light emitting diode (micro-LED) of a flip-chip type, but the embodiment of the disclosure is not limited thereto.

In an embodiment, as shown in FIGS. 2 and 3, the area of the first sub-pixel RP, the area of the second sub-pixel GP, and the area of the third sub-pixel BP may be substantially the same as each other in the plan view, but the embodiment of the disclosure is not limited thereto. In another embodiment, at least one selected from the area of the first sub-pixel RP, the area of the second sub-pixel GP, and the area of the third sub-pixel BP may be different from another one. Alternatively, any two of the area of area of the first sub-pixel RP, the area of the second sub-pixel GP, and the area of the third sub-pixel BP may be substantially the same as each other, and the remaining one may be different from the two. Alternatively, the area of the first sub-pixel RP, the area of the second sub-pixel GP, and the area of the third sub-pixel BP may be different from each other.

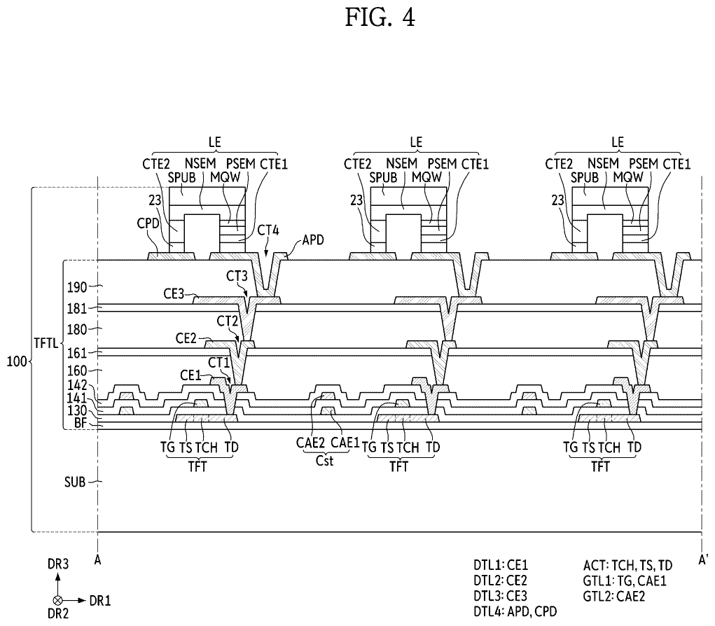

FIG. 4 is a cross-sectional view illustrating an embodiment of a display panel.

Referring to FIG. 4, an embodiment of the display panel 100 may include a thin film transistor layer TFTL and light emitting elements LE disposed on a substrate SUB. The thin film transistor layer TFTL may be a layer on which thin film transistors TFT are formed.

The thin film transistor layer TFTL may include an active layer ACT, a first gate layer GTL1, a second gate layer GTL2, a first data metal layer DTL1, a second data metal layer DTL2, a third data metal layer DTL3, and a fourth data metal layer DTL4. The thin film transistor layer TFTL may further include a buffer film BF, a gate insulating film 130, a first interlayer insulating film 141, a second interlayer insulating film 142, a first planarization film 160, a first insulating film 161, a second planarization film 180, and a second insulating film 181.

The substrate SUB may be a base substrate or a base member for supporting a display device. In an embodiment, the substrate SUB may be a rigid substrate including or made of glass, but the embodiments of the disclosure are not limited thereto. In another embodiment, the substrate SUB may be a flexible substrate capable of bending, folding, rolling, etc. In such an embodiment, the substrate SUB may include an insulating material such as a polymer resin such as polyimide (PI).

A buffer film BF may be disposed on one surface of the substrate SUB. The buffer film BF may be a film for preventing the penetration of air or moisture. The buffer film BF may be formed of or defined by a plurality of inorganic films alternately laminated. In an embodiment, for example, the buffer film BF may be formed as a multilayer of alternately stacked inorganic films of at least one selected from a silicon nitride layer, a silicon oxynitride layer, a silicon oxide layer, a titanium oxide layer, and an aluminum oxide layer. In another embodiment, the buffer film BF may be omitted.

An active layer ACT may be disposed on the buffer film BF. The active layer ACT may include a silicon semiconductor, such as polycrystalline silicon, monocrystalline silicon, low-temperature polycrystalline silicon, and amorphous silicon, or may include an oxide semiconductor.

The active layer ACT may include a channel TCH, a first electrode TS, and a second electrode TD of a thin film transistor TFT. The channel TCH of the thin film transistor TFT may be an area overlapping a gate electrode TG of the thin film transistor TFT in the third direction DR3 that is a thickness direction of the substrate SUB. The first electrode TS of the thin film transistor TFT may be disposed at one side end of the channel TCH, and the second electrode TD may be disposed at an opposing side end of the channel TCH. The first electrode TS and the second electrode TD of the thin film transistor TFT may be areas that do not overlap the gate electrode TG in the third direction DR3. The first electrode TS and the second electrode TD of the thin film transistor TFT may be areas in which ions are doped in a silicon semiconductor or an oxide semiconductor to have conductivity.

A gate insulating film 130 may be disposed on the active layer ACT. The gate insulating film 130 may include or be formed of an inorganic film, such as a silicon nitride layer, a silicon oxynitride layer, a silicon oxide layer, a titanium oxide layer, or an aluminum oxide layer.

A first gate layer GTL1 may be disposed on the gate insulating film 130. The first gate layer GTL1 may include the gate electrode TG of the thin film transistor TFT and the first capacitor electrode CAE1. The first gate layer GTL1 may be formed as a single layer or multiple layers, each layer herein including at least one selected from molybdenum (Mo), aluminum (AI), chromium (Cr), gold (Au), titanium (Ti), nickel (Ni), neodymium (Nd), and copper (Cu), or an alloy thereof.

A first interlayer insulating film 141 may be disposed on the first gate layer GTL1. The first interlayer insulating film 141 may include or be formed of an inorganic film, such as a silicon nitride layer, a silicon oxynitride layer, a silicon oxide layer, a titanium oxide layer, or an aluminum oxide layer.

A second gate layer GTL2 may be disposed on the first interlayer insulating film 141. The second gate layer GTL2 may include a second capacitor electrode CAE2. The second gate layer GTL2 may be formed as a single layer or multiple layers, each layer therein including at least one selected from molybdenum (Mo), aluminum (AI), chromium (Cr), gold (Au), titanium (Ti), nickel (Ni), neodymium (Nd), and copper (Cu), or an alloy thereof.

A second interlayer insulating film 142 may be disposed on the second gate layer GTL2. The second interlayer insulating film 142 may include or be formed of an inorganic film, such as a silicon nitride layer, a silicon oxynitride layer, a silicon oxide layer, a titanium oxide layer, or an aluminum oxide layer.

A first data metal layer DTL1 including a first connection electrode CE1, a first sub-pad SPD1, and a data line DL may be disposed on the second interlayer insulating film 142. The data line DL may be formed integrally with the first sub-pad SPD1 as a single unitary indivisible part, but the embodiment of the disclosure is not limited thereto. The first data metal layer DTL1 may be formed as a single layer or multiple layers, each layer therein including at least one selected from molybdenum (Mo), aluminum (Al), chromium (Cr), gold (Au), titanium (Ti), nickel (Ni), neodymium (Nd), and copper (Cu), or an alloy thereof.

A first connection electrode CE1 may be connected to the first electrode TS or the second electrode TD of the thin film transistor TFT through the first contact hole CT1 defined in the first interlayer insulating film 141 and the second interlayer insulating film 142.

A first planarization film 160 may be disposed on the first data metal layer DTL1 to planarize the step caused by the active layer ACT, the first gate layer GTL1, the second gate layer GTL2, and the first data metal layer DTL1. The first planarization film 160 may include or be formed of an organic film such as an acrylic resin, an epoxy resin, a phenolic resin, a polyamide resin, a polyimide resin, or the like.

A second data metal layer DTL2 may be disposed on the first planarization film 160. The second data metal layer DTL2 may include a second connection electrode CE2 and a second sub pad PD2. The second connection electrode CE2 may be connected to the first connection electrode CE1 through a second contact hole CT2 penetrating the first insulating film 161 and the first planarization film 160. The second data metal layer DTL2 may be formed as a single layer or multiple layers, each layer therein including at least one selected from molybdenum (Mo), aluminum (AI), chromium (Cr), gold (Au), titanium (Ti), nickel (Ni), neodymium (Nd), and copper (Cu), or an alloy thereof.

A second planarization film 180 may be disposed on the second data metal layer DTL2. The second planarization film 180 may include or be formed of an organic film, such as an acrylic resin, an epoxy resin, a phenolic resin, a polyamide resin, a polyimide resin, or the like.

A third data metal layer DTL3 may be disposed on the second planarization film 180. The third data metal layer DTL3 may include a third connection electrode CE3 and a third sub pad SPD3. The third connection electrode CE3 may be connected to the second connection electrode CE2 through a third contact hole CT3 defined in the second insulating film 181 and the second planarization film 180. The third data metal layer DTL3 may be formed as a single layer or multiple layers, each layer therein including at least one selected from molybdenum (Mo), aluminum (AI), chromium (Cr), gold (Au), titanium (Ti), nickel (Ni), neodymium (Nd), and copper (Cu), or an alloy thereof.

A third planarization film 190 may be disposed on the third data metal layer DTL3. The third planarization film 190 may include or be formed of an organic film, such as an acrylic resin, an epoxy resin, a phenolic resin, a polyamide resin, a polyimide resin, or the like.

A fourth data metal layer DTL4 may be disposed on the third planarization film 190. The fourth data metal layer DTL4 may include an anode pad electrode APD, a cathode pad electrode CPD, and a fourth sub pad SPD. The anode pad electrode APD may be connected to a third connection electrode CE3 through a fourth contact hole CT4 defined in the third insulating film 191 and the third planarization film 190. The cathode pad electrode CPD may be supplied with a first power supply voltage that is a low potential voltage. The fourth data metal layer DTL4 may be formed as a single layer or multiple layers, each layer therein including at least one selected from molybdenum (Mo), aluminum (AI), chromium (Cr), gold (Au), titanium (Ti), nickel (Ni), neodymium (Nd), and copper (Cu), or an alloy thereof.

A transparent conductive layer TCO may be disposed on each of the anode pad electrode APD and the cathode pad electrode CPD to increase adhesion to the first contact electrode CTE1 and the second contact electrode CTE2 of the light emitting element LE. The transparent conductive layer TCO may include or be formed of a transparent conductive oxide, such as indium tin oxide (ITO) and indium zinc oxide (IZO). In other embodiments, the transparent conductive layer TCO may be omitted.

A protective film PVX may be disposed on the anode pad electrode APD, the cathode pad electrode CPD, and the first pad PD1. The protective film PVX may be disposed to cover the edges of the anode pad electrode APD, the cathode pad electrode CPD, and the first pad PD1. The protective film PVX may include or be formed of an inorganic film, such as a silicon nitride layer, a silicon oxynitride layer, a silicon oxide layer, a titanium oxide layer, or an aluminum oxide layer. In other embodiment, the protective film PVX may be omitted.

The light emitting element LE is exemplified as a flip-chip type micro LED in which the first contact electrode CTE1 and the second contact electrode CTE2 are disposed to face the anode pad electrode APD and the cathode pad electrode CPD but is not limited thereto. The light emitting element LE may be an inorganic light emitting element made of an inorganic material such as GaN. The light emitting element LE may have a length in the first direction DR1, a length in the second direction DR2, and a length in the third direction DR3 of several to several hundred μm, respectively. In an embodiment, for example, the light emitting element LE may have a length in the first direction DR1, a length in the second direction DR2, and a length in the third direction DR3 of about 100 μm or less, respectively.

The light emitting elements LE may be grown and formed on a semiconductor substrate such as a silicon wafer. Each of the light emitting elements LE may be transferred directly from the silicon wafer onto the anode pad electrode APD and the cathode pad electrode CPD of the substrate SUB. In this case, the first contact electrode CTE1 and the anode pad electrode APD may be bonded to each other through a bonding process. Further, the second contact electrode CTE2 and the cathode pad electrode CPD may be bonded to each other through the bonding process. The first contact electrode CTE1 and the anode pad electrode APD may be electrically connected to each other through a bonding electrode 23. Furthermore, the second contact electrode CTE2 and the cathode pad electrode CPD may be electrically connected to each other through the bonding electrode 23.

In an embodiment, for example, the bonding electrode 23 may be disposed on one side of the light emitting element LE. The bonding electrode 23 may be a bonding product of pressurized melting bonding using a laser. Here, the pressurized melting bonding refers to a state in which the bonding electrode 23 is heated and melted, and the light emitting element LE, the anode pad electrode APD, and the cathode pad electrode CPD are melted and mixed, and then cooled and solidified when the laser supply is terminated. Since the conductivity of the light emitting element LE, the anode pad electrode APD, and the cathode pad electrode CPD is maintained while being cooled and solidified in a melted and mixed state, the anode pad electrode APD, the cathode pad electrode CPD and the light emitting element LE may be electrically and physically connected to each other. Accordingly, the bonding electrode 23 may be disposed on the first contact electrode CTE1 and the second contact electrode CTE2 of the light emitting element LE.

The bonding electrode 23 may include, for example, Au, AuSn, PdIn, InSn, NiSn, Au—Au, AgIn, AgSn, Al, Ag, or carbon nanotubes CNT. Each of these may be used alone or in combination of two or more. Depending on the type of the bonding electrode 23, the bonding electrode 23 may be formed by deposition on the pad electrode or may be formed on the pad electrode by various methods, such as screen printing.

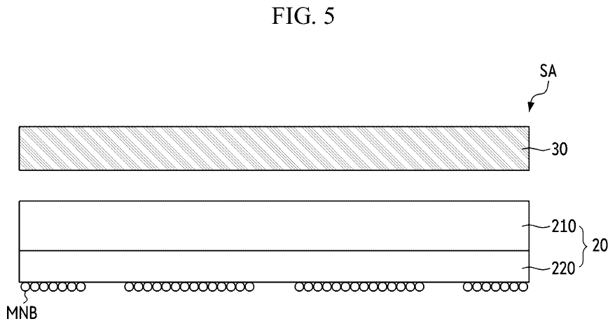

Alternatively, each of the light emitting elements LE may be transferred onto the anode pad electrode APD and the cathode pad electrode CPD of the substrate SUB using a transfer member. This will be described later with reference to FIGS. 5 to 19.

Each of the light emitting elements LE may be a light emitting structure including a base substrate SPUB, an n-type semiconductor NSEM, an active layer MQW, a p-type semiconductor PSEM, a first contact electrode CTE1, and a second contact electrode CTE2.

The base substrate SPUB may be a sapphire substrate, for example, but the embodiments of the disclosure are not limited thereto.

The n-type semiconductor NSEM may be disposed on one surface of the base substrate SPUB. In an embodiment, for example, the n-type semiconductor NSEM may be disposed on a bottom surface of the base substrate SPUB. The n-type semiconductor NSEM may include or be made of GaN doped with n-type conductive dopants such as Si, Ge, Sn, and the like.

The active layer MQW may be disposed on a portion of one surface of the n-type semiconductor NSEM. The active layer MQW may include a material having a single or multiple quantum well structure. In an embodiment where the active layer MQW includes a material having a multi-quantum well structure, the active layer MQW may have a structure in which multiple well layers and barrier layers are alternately laminated. In such an embodiment, the well layers may include or be formed of InGaN, and the barrier layers may include or be formed of GaN or AlGaN but are not limited thereto. Alternatively, the active layer MQW may have a structure in which semiconductor materials having a large band gap energy and semiconductor materials having a small band gap energy are alternately laminated and may include different group Ill to group V semiconductor materials depending on the wavelength of the light emitted.

In an embodiment, as shown in FIG. 4, each of the light emitting elements LE may be a flip-type light emitting element in which the first contact electrode CTE1 and the second contact electrode CTE2 are disposed on one side (or a same side) of the light emitting element LE, but is not limited thereto, and may also be a vertical light emitting element in which the first contact electrode CTE1 and the second contact electrode CTE2 are respectively disposed on both opposing ends of the light emitting element LE.

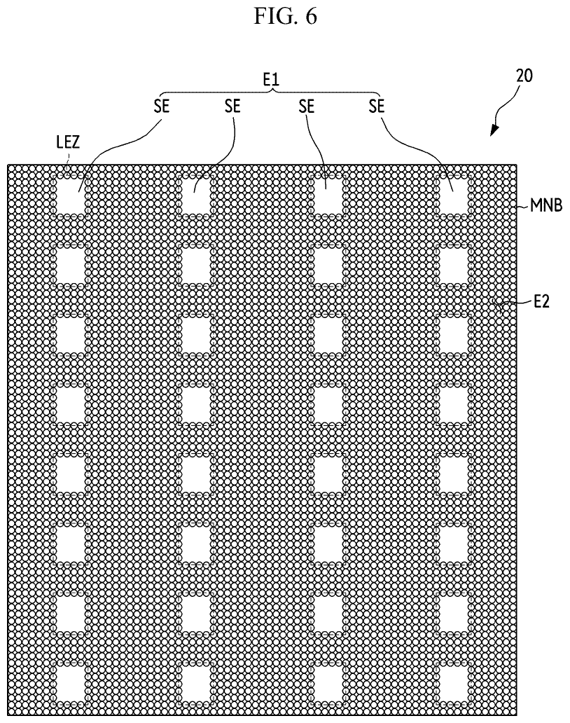

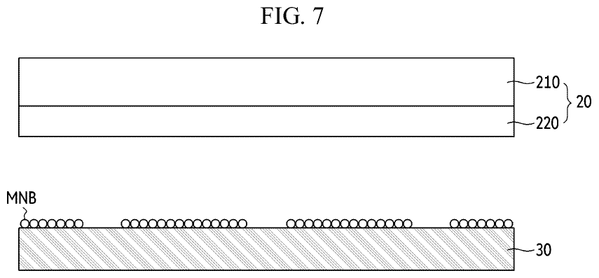

FIG. 5 is a side view illustrating the structure of a stamp assembly according to an embodiment. FIG. 6 is a front view illustrating a plurality of magnetic beads disposed on one surface of a stamp member according to an embodiment. FIG. 7 is a side view illustrating the structure of a stamp assembly according to an embodiment.

Referring to FIGS. 5 and 6, an embodiment of the stamp assembly SA may include a stamp member 20, a magnetic plate 30, and a plurality of magnetic beads MNB.

In an embodiment, the stamp member 20 include or is formed of a material that transmits laser, and includes a base layer 210 and a stamp layer 220 disposed on one surface of the base layer 210.

The base layer 210 may include or be formed of, for example, glass or plastic. In an embodiment where the base layer 210 includes or is defined by a thin glass, the glass may be an ultra-thin tempered glass. Alternatively, the base layer 210 may include or be made of polyethylene terephthalate (PET), polyurethane (PU), polyimide (PI), polycarbonate (PC), polyethylene (PE), polypropylene (PP), polysulfone (PSF), polymethylmethacrylate (PMMA), triacetylcellulose (TAC), cycloolefin polymer (COP), or the like.

The stamp layer 220 may include or be made of, but is not limited to, acrylic, urethane, or silicone materials.

The stamp layer 220 may have elasticity and adhesiveness on one side. That is, one surface portion of the stamp layer 220 may have a modulus, such as Young's modulus, the shear modulus, and the bulk modulus, greater than a predetermined value, and an adhesive force greater than a predetermined value with respect to a predetermined surface.

The plurality of magnetic beads MNB are ferromagnetic particles, have a size (e.g., an average size such as an average width or diameter) of about 10 nm, and have a uniform particle distribution. In addition, each magnetic bead may have a high saturation magnetization value and magnetization rate not to aggregate with each other and to react sensitively to changes in an external (or externally induced) magnetic field.

In an embodiment, a plurality of magnetic beads MNB may be disposed on one surface of the stamp layer 220. The plurality of magnetic beads MNB may be arranged in a single layer without being cohesive to each other on one surface of the stamp layer 220.

One surface of the stamp layer 220 may be divided into a first area E1 where the magnetic beads MNB are not disposed and a second area E2 where the magnetic beads MNB are disposed. The first area E1 may include a plurality of sub-areas SE spaced apart from each other in a plan view. The plurality of sub-areas SE may form columns and rows on one surface of the stamp layer 220.

The first area E1 may be smaller than the area LEZ where the light-emitting element LE is disposed (or the area LEZ occupied by the light-emitting element LE) in the plan view. The second area E2 may be an area excluding the first area E1. The area LEZ where the light emitting element LE is disposed has a same size and shape as one surface of the light emitting element LE. Therefore, the area of the sub-area SE may be smaller than the area of one side of the light emitting element LE.

The plurality of magnetic beads MNB may be disposed in a single layer in the second area E2. Further, the magnetic beads MNB surrounding the sub-area SE in the second area E2 may overlap the area LEZ where the light emitting element LE is disposed.

The plurality of magnetic beads MNB may be disposed using a method of patterning a surface of the stamp layer 220 using photoresist, a method of pick-and-plying with a separate stamp, a method of applying one or more external forces such as static electricity or magnetic force, etc.

The magnetic plate 30 may have an area that may cover the entire stamp layer 220.

The magnetic plate 30 may be detachably disposed on the top or bottom side of the stamp member 20. In an embodiment, for example, the magnetic plate 30 may be detachably disposed on the upper portion of the base layer 210.

When the magnetic plate 30 is disposed on one surface of the base layer 210, the magnetic bead MNB may be fixed by the attractive force between the magnetic plate 30 and the magnetic bead MNB disposed on one surface of the stamp layer 220.

The magnetic plate 30 may be a permanent magnet or an electromagnet.

In an embodiment, referring to FIG. 7, where the magnetic bead MNB is disposed on one surface of the stamp layer 220, the magnetic plate 30 may be disposed on the bottom surface of the stamp layer 220. In an embodiment, for example, the magnetic plate 30 may be placed to face the magnetic bead MNB.

In an embodiment where the magnetic plate 30 is disposed on the bottom surface of the stamp member 20, an attractive force occurs between the magnetic bead MNB and the magnetic plate 30. The magnetic bead MNB is pulled downward in the direction where the magnetic plate 30 is disposed by the attractive force between the magnetic bead MNB and the magnetic plate 30. As a result, the magnetic bead MNB may be detached from the bottom surface of the stamp member 20 (e.g., one surface of the stamp layer 220) and disposed on the top surface of the magnetic plate 30.

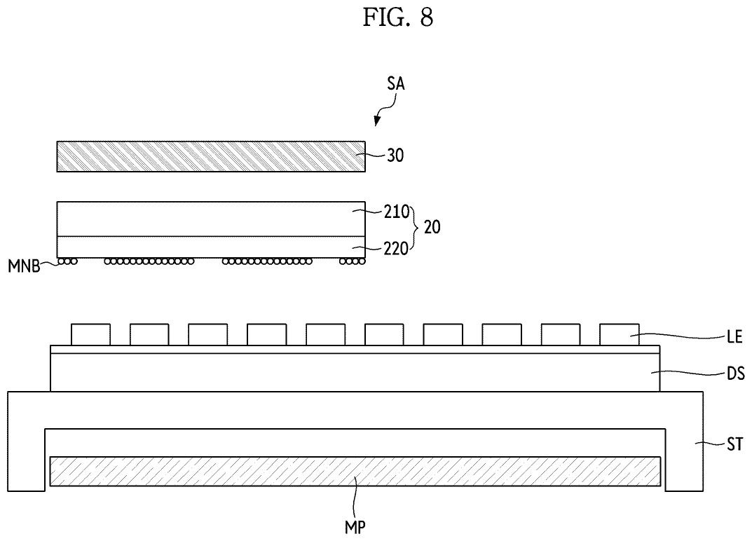

FIG. 8 is a diagram illustrating a light emitting element transfer device according to an embodiment.

An embodiment of the light emitting element transfer device may include a stamp assembly SA, a stage ST, and a magnetic plate MP. The stamp assembly SA may be substantially the same as the stamp assembly SA described with reference to the descriptions of FIGS. 5 to 7. In an embodiment described with reference to FIG. 8, the magnetic plate 30 of the stamp assembly SA is referred to as a first magnetic plate 30, and the magnetic plate MP of the light emitting element transfer device is referred to as a second magnetic plate MP to distinguish it from the magnetic plate 30 of the stamp assembly SA. The second magnetic plate MP may be a permanent magnet or an electromagnet.

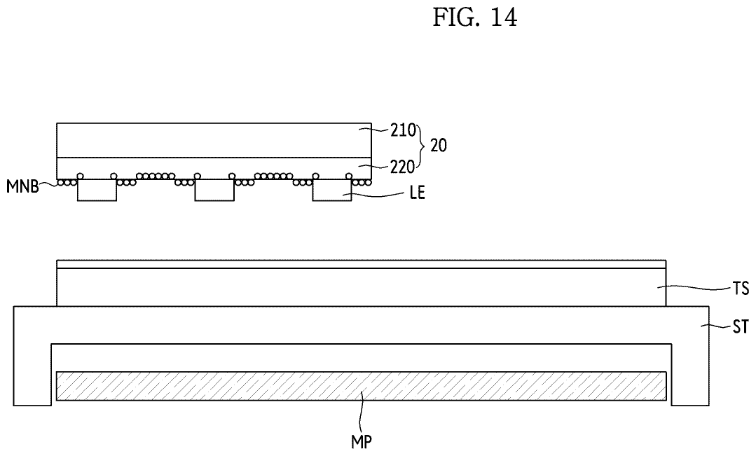

The stage ST serves to support a substrate. The substrate may be a donor substrate DS or a target substrate (e.g., TS in FIG. 14), which is a display substrate. The donor substrate DS may include an adhesive layer on a top surface but is not limited thereto. The donor substrate DS may be disposed on the stage ST. The light emitting elements LE are disposed or formed on the donor substrate DS.

The second magnetic plate MP may have an area that covers the entire stamp layer 220.

The second magnetic plate MP may be detachably placed under the stage ST. In an embodiment, where the second magnetic plate MP is an electromagnet, the second magnetic plate MP may be fixedly disposed under the stage ST.

The stamp member 20 may be disposed on the upper portion of the stage ST, and the first magnetic plate 30 may be disposed on the upper portion of the stamp member 20.

The position of the magnetic bead MNB may be changed depending on the magnetic force of the first magnetic plate 30 and the second magnetic plate MP.

In an embodiment, for example, if the first magnetic plate 30 and the second magnetic plate MP are each permanent where, the magnetic bead MNB may be disposed at one surface of the stamp member 20 when the first magnetic plate 30 is in contact with one surface of the stamp member 20 and the second magnetic plate MP is positioned at a position where it is not subjected to a magnetic force from the stage ST. In an embodiment, where the first magnetic plate 30 is disposed at a position where it is not subjected to a magnetic force from the stamp member 20, the second magnetic plate MP is disposed at one surface of the stage, and the stamp member 20 is disposed at a position where it is subjected to a magnetic force from the light emitting element LE, the stamp member 20 is disposed within a range where the magnetic force of the second magnetic plate MP is applied. Accordingly, the magnetic bead MNB disposed at one surface of the stamp member 20 may be detached from the one surface of the stamp member 20 and transferred to the donor substrate DS.

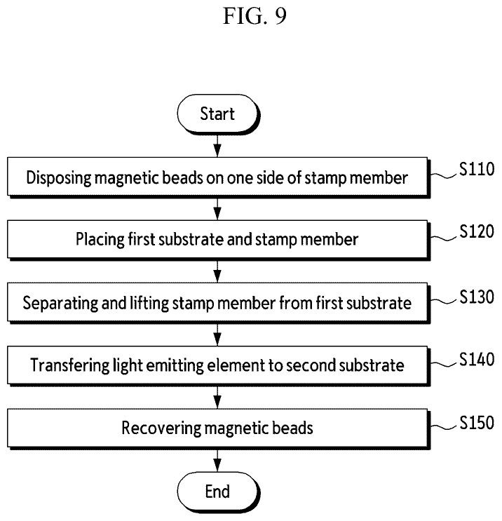

FIG. 9 is a flow chart illustrating a light emitting element transfer method according to an embodiment.

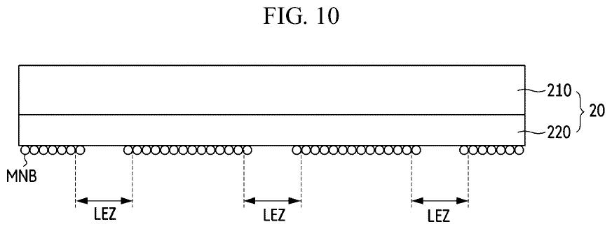

FIGS. 10 to 19 are cross-sectional views to illustrate a light emitting element transfer method according to an embodiment. FIGS. 10 to 19 are cross-sectional views to illustrate a method of transferring a light emitting element using the light emitting element display device described with reference to FIG. 8. The stamp assembly SA described in FIGS. 10 to 19 may correspond to the stamp assembly SA described with reference to FIGS. 5 to 7.

In the following, the light emitting element transfer method illustrated in FIGS. 10 to 19 will be illustrated in connection with FIG. 9.

In an embodiment of the light emitting element transfer method, magnetic beads MNB are disposed on one side (or one surface) of a stamp member 20 (S110 in FIG. 9).

Referring to FIG. 10, a plurality of magnetic beads MNB may be disposed using a method of patterning a surface of a stamp layer 220 using a photoresist, a method of pick-and-plying with a separate stamp, a method of applying one or more external forces such as static electricity or magnetic force, etc.

As described with reference to FIG. 6, a plurality of magnetic beads MNB are disposed in the second area E2 of the stamp layer 220.

Subsequently, a first substrate (or a doner substrate) DS and a stamp member 20 may be disposed or placed on the stage ST (S120 in FIG. 9).

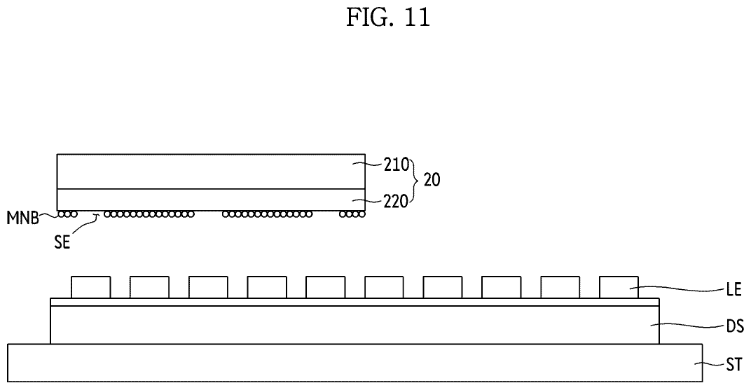

Referring to FIG. 11, an adhesive layer may be applied on the first substrate DS. A plurality of light emitting elements LE are disposed on the adhesive layer of the first substrate DS.

The first substrate DS may be disposed on the stage ST in a way such that the plurality of light emitting elements LE are positioned on top or thereabove.

The stamp member 20 may be disposed on the first substrate DS, and the plurality of magnetic beads MNB disposed on one surface of the stamp member 20 may be disposed in a way such that the stamp member 20 and the plurality of magnetic beads MNB face the plurality of light emitting elements LE.

The stamp member 20 may be disposed in a way such that the sub-area SE of the stamp layer 220 overlaps the light emitting element LE in a thickness direction of the stamp member 20.

The sub-areas SE may be disposed in a way such that the sub-areas SE overlap the light emitting element LE in the thickness direction of the stamp member 20.

Subsequently, the light emitting elements LE disposed on the first substrate DS are lifted by separating the light emitting elements LE from the first substrate DS using the stamp member 20 (S130 in FIG. 9).

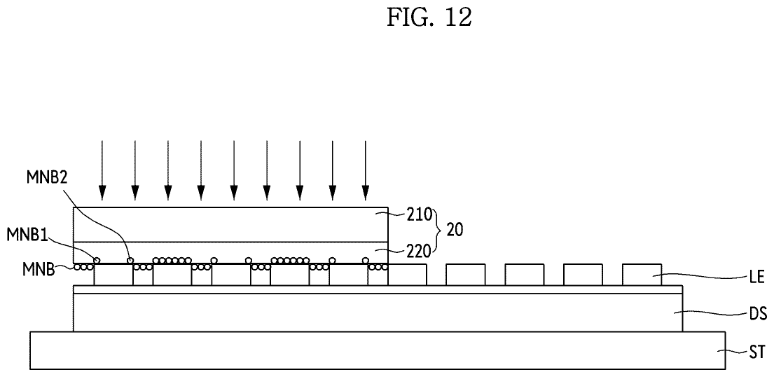

Referring to FIG. 12, the stamp member 20 is brought into (or moved to be in) contact with one surface of the light emitting element LE, and the stamp member 20 presses the light emitting element LE downward from the top.

The sub-area SE of the stamp member 20 overlaps the light emitting element LE, but since the area of the sub-area SE is smaller than the area of one surface of the light emitting element LE, some of the magnetic beads MNB1 and MNB2 surrounding the sub-area SE are disposed on the top surface of the light emitting element LE. That is, some magnetic beads MNB1 and MNB2 surrounding the sub-area SE overlap the outer surface of the light emitting element LE. By applying pressure, the magnetic beads MNB1 and MNB2 overlapping the outer surface of the light emitting element LE are embedded into the inside of the stamp layer 220, and the light emitting element LE is adhered to the stamp layer 220 of the sub-area SE.

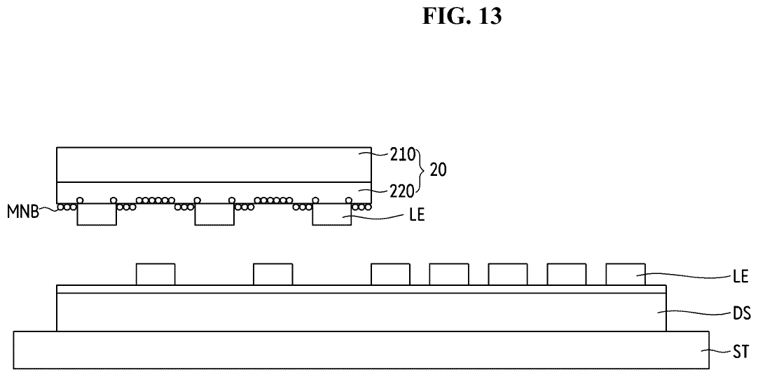

Thereafter, referring to FIG. 13, the stamp member 20 lifts the light emitting element LE.

In such an embodiment, the adhesive force of the stamp layer 220 to the light emitting element LE is greater than the adhesive force of the first substrate DS to the light emitting element LE. Therefore, when the stamp member 20 is lifted, the light emitting elements LE may be separated from the first substrate DS and lifted along the stamp member 20.

Subsequently, the light emitting elements LE are transferred onto the second substrate (or a target substrate) TS using the stamp member 20 (S140 in FIG. 9).

Referring to FIG. 14, the stamp member 20 is aligned on the top side of the second substrate TS in a predetermined position.

The second substrate TS may be a target substrate on which the light emitting element is to be transferred and may be a different relay substrate from the first substrate, but is not limited thereto. In an embodiment, for example, the second substrate TS may be a backplane substrate for manufacturing the display panel 100 described in FIG. 4.

In an embodiment where the second substrate TS is a different relay substrate, an adhesive layer may be disposed on the top surface. The adhesive strength of the adhesive layer of the second substrate TS to the light emitting element LE may be greater the adhesive strength of the stamp layer 220 to the light emitting element LE.

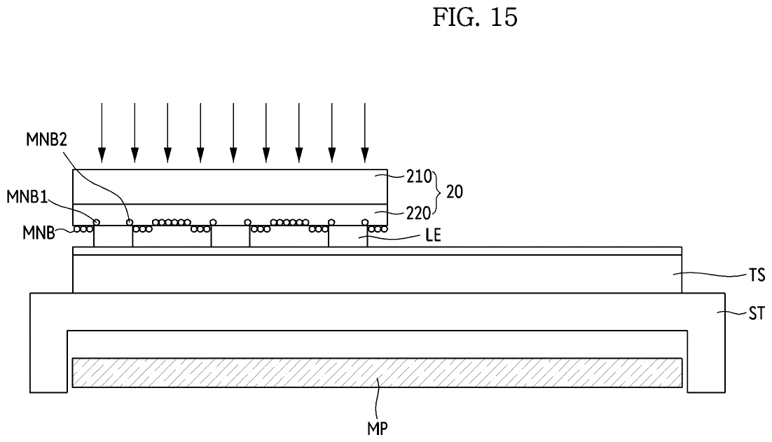

Referring to FIG. 15, after the light emitting element LE is brought into contact with the upper surface of the second substrate TS, the stamp member 20 presses the light emitting element LE downward from the upper side.

When the adhesive layer is disposed on the second substrate TS, the light emitting element LE is adhered to the adhesive layer of the second substrate TS.

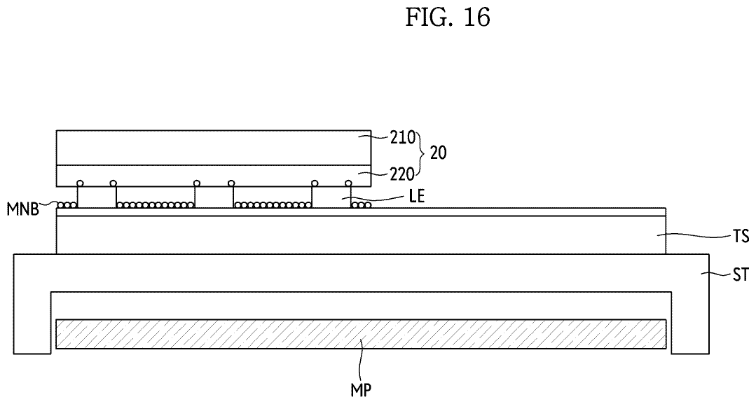

Next, referring to FIG. 16, when the second magnetic plate MP is disposed on the bottom surface of the stage ST, an attractive force is generated between the magnetic beads MNB of the stamp member 20 and the second magnetic plate MP. Therefore, the magnetic beads MNB are pulled downward in the direction where the second magnetic plate MP is disposed by the attractive force between the magnetic beads MNB and the second magnetic plate MP. At this time, the magnetic beads MNB1 and MNB2 disposed above the light emitting element LE are also pulled downward. Therefore, the magnetic beads MNB1 and MNB2 press the light emitting element LE downward. The pressure of the magnetic beads MNB1 and MNB2 resulting from the attraction with the second magnetic plate MP may act as a supplemental force in the separation of the light emitting element LE from the stamp member 20.

In an embodiment where the second magnetic plate MP is a permanent magnet, as illustrated in FIG. 16, the second magnetic plate MP may be attached and detached from the stage ST to apply a magnetic force to the magnetic beads. In an embodiment, for example, the second magnetic plate MP may be attached to the stage ST to apply a magnetic force to the magnetic beads, and the second magnetic plate MP may be detached and detached from the stage ST to prevent the magnetic force from being applied to the magnetic beads.

In another embodiment where the second magnetic plate MP is an electromagnet, the second magnetic plate MP may apply a magnetic force to the magnetic beads by controlling the current while attached to the stage ST. In an embodiment, for example, the second magnetic plate MP may be attached to the stage ST and applied with current to apply a magnetic force to the magnetic beads and may prevent the magnetic force from being applied to the magnetic beads by not applying current.

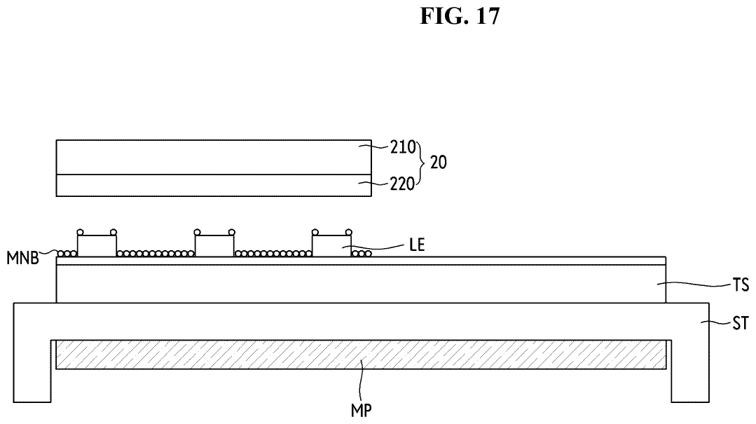

In an embodiment, for example, referring to FIG. 17, the stamp member 20 is lifted to separate the light emitting element LE and the stamp member 20 from each other.

In this process, the magnetic beads MNB1 and MNB2 disposed above the light emitting element LE may enhance preventing the light emitting element LE from being lifted along the stamp member 20 by pressing the light emitting element LE downward.

Subsequently, a plurality of magnetic beads MNB are recovered from the second substrate TS to the stamp member 20 (S150 in FIG. 9).

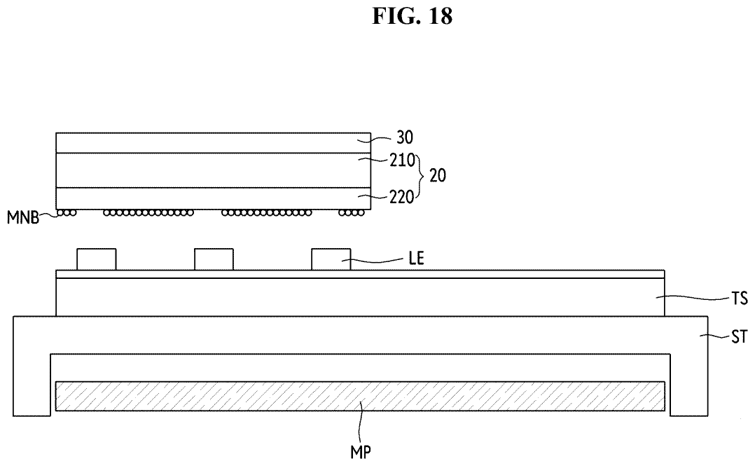

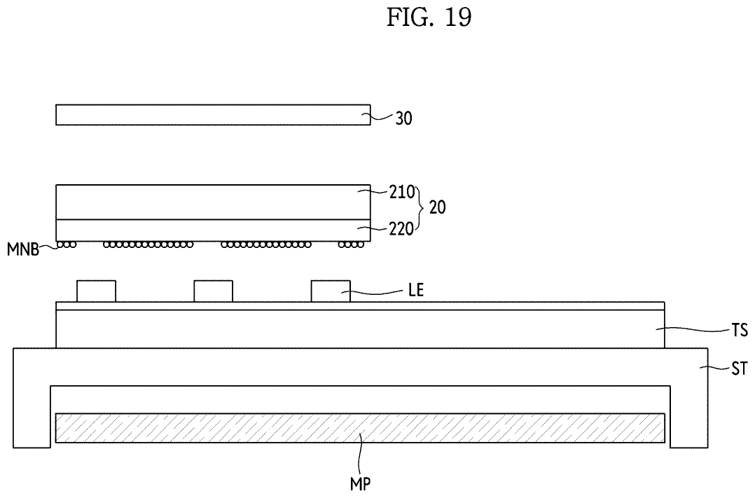

Referring to FIG. 18 and FIG. 19, the second magnetic plate MP is moved to a position where it does not exert a magnetic force on the plurality of magnetic beads MNB, and the first magnetic plate 30 is placed on the upper portion of the stamp member 20 (the upper portion of the base layer 210). When the first magnetic plate 30 is disposed on the upper portion of the stamp member 20, an attractive force is generated between the plurality of magnetic beads MNB and the first magnetic plate 30, thereby pulling the plurality of magnetic beads MNB toward the first magnetic plate 30. As a result, the plurality of magnetic beads MNB may be recovered from the second substrate TS to the stamp member 20.

According to embodiments of the disclosure, by using magnetic beads to pick up the light emitting element, the light emitting element may be substantially completely transferred during a transfer process and effectively prevented from being remaining on the donor substrate or stamp surface. Accordingly, the product quality and yield of the display device during the transfer process may be increased.

In such embodiments, since the repair process and stamp cleaning process may be omitted, the equipment cost and process cost may be reduced.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A stamp assembly comprising:
a stamp member including a stamp layer and a base layer;
a magnetic plate which applies a magnetic force on a top surface of the base layer; and
a plurality of magnetic beads which are attachable and detachable to the stamp layer by the magnetic force of the magnetic plate.

2. The stamp assembly of claim 1, wherein the magnetic beads are ferromagnetic particles having a size of about 10 nm or less.

3. The stamp assembly of claim 1, wherein the stamp layer is divided into a first area where the magnetic beads are not disposed and a second area where the magnetic beads are not disposed,
wherein the first area includes a plurality of sub-areas.

4. The stamp assembly of claim 3, wherein the sub-areas correspond to positions where the light emitting elements are to be attached, and an area of the sub-areas is smaller than an area of one surface of the light emitting elements.

5. The stamp assembly of claim 1, wherein a surface portion of the stamp layer has elasticity and adhesiveness.

6. The stamp assembly of claim 1, wherein the magnetic plate is an electromagnet or a permanent magnet.

7. A light emitting element transfer device comprising:
a stage which supports a substrate;
a stamp member including a stamp layer and a base layer;
a first magnetic plate which applies a magnetic force on a top surface of the base layer;
a plurality of magnetic beads which are attachable and detachable to the stamp layer by the magnetic force of the first magnetic plate; and
a second magnetic plate which is disposed on a bottom surface of the stage and applies a magnetic force to the bottom surface of the stage.

8. The device of claim 7, wherein the stamp layer is divided into a first area where the magnetic beads are not disposed and a second area where the magnetic beads are not disposed,
wherein the first area includes a plurality of sub-areas.

9. The device of claim 8, wherein the sub-areas correspond to positions where the light emitting elements are to be attached, and an area of the sub-areas is smaller than an area of one side of the light emitting elements.

10. The device of claim 8,
wherein the substrate includes at least one selected from a donor substrate, on which the light emitting elements are disposed, and a target substrate, to which the light emitting elements are to be transferred from the donor substrate.

11. The device of claim 7, wherein a surface portion of the stamp layer has elasticity and adhesiveness.

12. The device of claim 7, wherein each of the first magnetic plate and the second magnetic plate is an electromagnet or a permanent magnet.

13. A method for transferring light emitting elements, the method comprising:
arranging a plurality of magnetic beads on one surface of a stamp member;
disposing the stamp member on a donor substrate in a way such that the magnetic beads face light emitting elements on the donor substrate;
lifting the light emitting elements with the stamp member;
disposing the stamp member on a target substrate in a way such that the light emitting elements face the target substrate;
disposing a first magnetic plate under the target substrate and transferring the light emitting elements and the magnetic beads to the target substrate; and
disposing a second magnetic plate on a top surface of the stamp member and recovering the magnetic beads.

14. The method of claim 13,
wherein the stamp member includes a stamp layer having adhesiveness on one surface of the light emitting elements, and
wherein in the lifting the light emitting elements with the stamp member, the light emitting elements are lifted by applying a pressure to adhere the light emitting elements to the stamp layer.

15. The method of claim 14, wherein the stamp layer is divided into a first area where the magnetic beads are not disposed and a second area where the magnetic beads are disposed,
wherein the first area includes a plurality of sub-areas,
wherein the sub-areas correspond to positions where the light emitting elements are to be attached, and
wherein an area of the sub-areas is smaller than an area of one surface of the light emitting elements.

16. The method of claim 15, wherein, when the stamp member comes into contact with the light emitting elements, some of the magnetic beads disposed in the second area and surrounding the sub-areas are disposed on a top surface of the light emitting elements and are embedded into a stamp layer of the stamp member by the pressure of the stamp member, such that one surface of the light emitting elements is adhered to the stamp layer.

17. The method of claim 13, in the disposing the first magnetic plate under the target substrate and the transferring the light emitting elements and the magnetic beads to the target substrate, the first magnetic plate is disposed under the target substrate and the magnetic beads disposed on one side of the stamp member are pulled in a downward direction by a magnetic force of the first magnetic plate, and the magnetic beads overlapping an upper portion of the light emitting elements press the light emitting elements in the downward direction.

18. The method of claim 17, wherein the first magnetic plate is a permanent magnet disposed close to a lower portion of the target substrate to exert the magnetic force on the magnetic beads.

19. The method of claim 17, wherein the first magnetic plate is an electromagnet fixed to a lower portion of a stage, on which the target substrate is disposed, and the first magnetic plate exerts the magnetic force on the magnetic bead by applying an electric current thereto.

20. The method of claim 13, the recovering the magnetic beads comprises disposing a second magnetic plate on a top surface of the stamp member,
wherein the second magnetic plate disposed on the top surface of the stamp member causes an attraction between the second magnetic plate and the magnetic beads to move the magnetic beads from the target substrate and a top surface of the light emitting elements to a bottom surface of the stamp member.
